(19) United States
(12) Patent Application Publication
(10) Pub. No.: US 2021/0104981 A1
(43) Pub. Date: Apr. 8, 2021

(54) PASSIVE MIXER WITH FEED-FORWARD CANCELLATION

(71) Applicant: QUALCOMM Incorporated, San Diego, CA (US)

(72) Inventors: Gary Lee BROWN, JR., Carlsbad, CA (US); Aleksandar Miodrag TASIC, San Diego, CA (US); Chirag Dipak PATEL, San Diego, CA (US)

(21) Appl. No.: 16/592,839

(22) Filed: Oct. 4, 2019

(51) Int. Cl. H03F 1/32; H03F 1/30; H04B 1/12; H04B 17/21; H03D 7/14

(52) U.S. Cl. CPC H03F 1/3235; H03F 1/30; H03D 7/1466; H04B 17/21; H04B 1/123

(57) ABSTRACT

A radio frequency (RF) front-end receiver having a passive mixer with feed-forward intermodulation distortion cancellation, or at least reduction. An example receiver generally includes a mixer having differential input terminals and differential output terminals and a baseband filter having inputs coupled to the differential output terminals of the mixer. The receiver also includes common-mode sensing circuitry coupled to the differential input terminals of the mixer and configured to sense a common-mode signal of a first differential signal present at the differential input terminals of the mixer. The receiver further includes a conversion circuit coupled to the common-mode sensing circuitry and configured to convert the common-mode signal to a second differential signal presented to the differential output terminals of the mixer and the inputs of the baseband filter.

### BACKGROUND

### Field of the Disclosure

Certain aspects of the present disclosure generally relate to electronic circuits and, more particularly, to a receiver having a passive mixer with a feed-forward path that reduces intermodulation distortion.

### Description of Related Art

Wireless communication networks are widely deployed to provide various communication services such as telephony, video, data, messaging, broadcasts, and so on. Such networks, which are usually multiple access networks, support communications for multiple users by sharing the available network resources. A wireless communication network may include a number of base stations that can support communication for a number of user equipment. A user equipment may communicate with a base station via a downlink and an uplink. The user equipment and/or base station may include a radio frequency (RF) front-end for transmitting and/or receiving radio frequency signals, and the receive path of the RF front-end may include any of various suitable types of mixers, such as a direct downconversion passive mixer.

Zero-IF (intermediate frequency) RF front-end architectures are attractive for cellular systems due to lower cost in terms of bill of materials (BOM) and area compared to IF architectures. A direct-conversion receiver, also known as a homodyne, synchrodyne, or zero-IF receiver, is a radio receiver design that demodulates incoming signals by mixing the received signals with a local oscillator (LO) signal synchronized in frequency to the carrier of the wanted signal. The demodulated signal is thus obtained immediately by low-pass filtering the mixer output, without further downconversion.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include an improved receiver that reduces intermodulation distortions generated by a passive mixer.

Certain aspects of the present disclosure provide a receiver. The receiver generally includes a mixer having differential input terminals and differential output terminals and a baseband filter having inputs coupled to the differential output terminals of the mixer. The receiver also includes common-mode sensing circuitry coupled to the differential input terminals of the mixer and configured to sense a common-mode signal of a first differential signal present at the differential input terminals of the mixer. The receiver further includes a conversion circuit coupled to the common-mode sensing circuitry and configured to convert the common-mode signal to a second differential signal presented to the differential output terminals of the mixer and the inputs of the baseband filter.

Certain aspects of the present disclosure provide a method of downconversion with a receiver. The method generally includes generating, with a mixer, a downconverted differential signal at a differential output of the mixer and filtering, with a baseband filter, the downconverted differential signal. The method also includes sensing, with common-mode sensing circuitry, a common-mode signal of a first differential signal present at a differential input of the mixer and converting, with a conversion circuit, the common-mode signal to a second differential signal. The method further includes applying, with the conversion circuit, the second differential signal between the differential output of the mixer and inputs of the baseband filter.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram showing an example radio frequency front-end, in accordance with certain aspects of the present disclosure.

FIG. 2 is a block diagram of an example receiver with a feed-forward path, in accordance with certain aspects of the present disclosure.

FIG. 3 is a schematic view of an example receiver with an in-phase (I) channel mixer, a quadrature (Q) channel mixer, and a feed-forward path for each mixer with a transconductor, in accordance with certain aspects of the present disclosure.

FIG. 4 is a schematic view of an example receiver with I and Q channel mixers and a feed-forward path for each mixer with a transconductance circuit having a voltage amplifier and a variable impedance circuit, in accordance with certain aspects of the present disclosure.

FIG. 5 is a flow diagram of example operations for downconversion with a receiver, in accordance with certain aspects of the present disclosure.

### DETAILED DESCRIPTION

Aspects of the present disclosure generally relate to the cancellation (or at least reduction) of intermodulation distortion (IMD) (e.g., a second-order intermodulation product (IM2)) output by a direct downconversion mixer, for example, in a receiver of an RF front-end. As an example, a conversion circuit may be electrically coupled on a feed-forward path from the input of the mixer to the output of the mixer, such that the conversion circuit applies a differential signal to the output of the mixer that offsets the differential-mode IM2 of the mixer. Cancelling the differential-mode IM2 output by the mixer may eliminate or reduce an interdependence between in-phase (I) and quadrature (Q) channels of the mixer, which may further enable a simplified calibration process of the receiver and, even more beneficial, an online calibration process. As used herein, canceling distortion (such as intermodulation distortion cancellation) may refer to eliminating the distortion or reducing the distortion.

### Example RE Front-End

In an RF front-end, the receiver downconverts received RF signals from RF to baseband frequencies, digitizes the baseband signal to generate samples, and digitally processes the samples to recover the data sent by a transmitter. The receiver uses one or more downconversion mixers to frequency downconvert the received RF signal from RF to baseband. In certain aspects, the receiver may use direct downconversion mixers (also referred to as zero intermediate frequency (zero-IF) mixers) that demodulate the incoming signal using synchronous detection driven by a local oscillator (LO) operating at a frequency that is identical to, or very close to, the carrier frequency.

An ideal mixer simply translates an input signal from one frequency to another frequency without distorting the input signal. In practical applications, however, a mixer has nonlinear characteristics that can result in the generation of various intermodulation components. One such intermodulation component is second-order intermodulation (IM2) distortion that is generated by second-order nonlinearity in the mixer. IM2 distortion is problematic for a downconversion mixer because the magnitude of the IM2 distortion may be large and the IM2 distortion may fall on top of the baseband signal, which can then degrade the performance of the receiver.

IM2 calibration may be performed on the receiver to ascertain the amounts of IM2 distortion in the in-phase (I) and quadrature (Q) baseband signals output by the mixers and to determine the amount of counteracting IM2 distortion to generate for each baseband signal in order to cancel the IM2 distortion in that baseband signal. IM2 calibration may be performed, for example, during manufacturing or testing of an RF integrated circuit (RFIC) that contains the downconversion mixer(s). Conventional IM2 calibration, however, takes significant test time with associated costs. Also, conventional IM2 calibration exhibits a strong inter-dependence between the I/Q channels of the mixer. As such, the I/Q channels of the mixer are often calibrated together, further increasing the complexity and test time of the calibration process. For instance, the calibration of the I/Q channels may employ a multi-point calibration, such as a 20-point calibration.

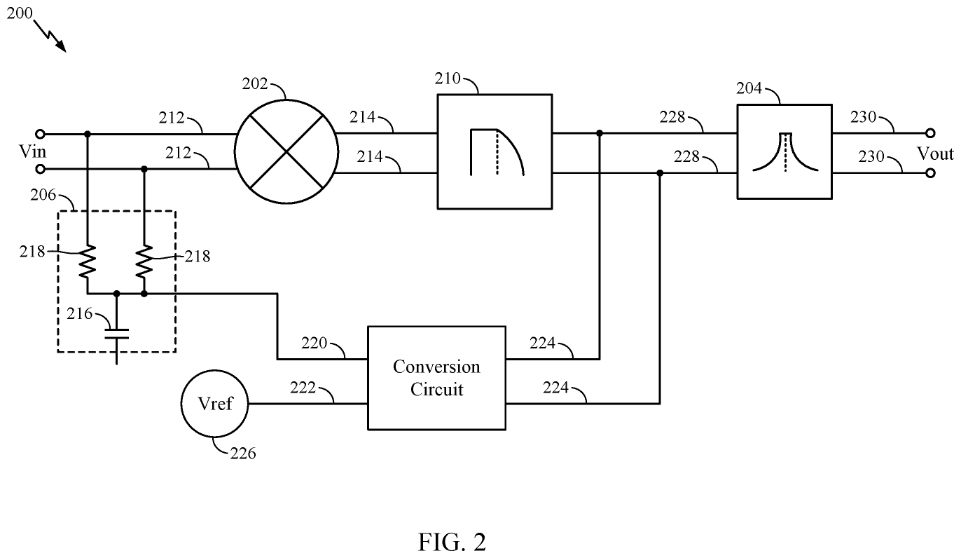

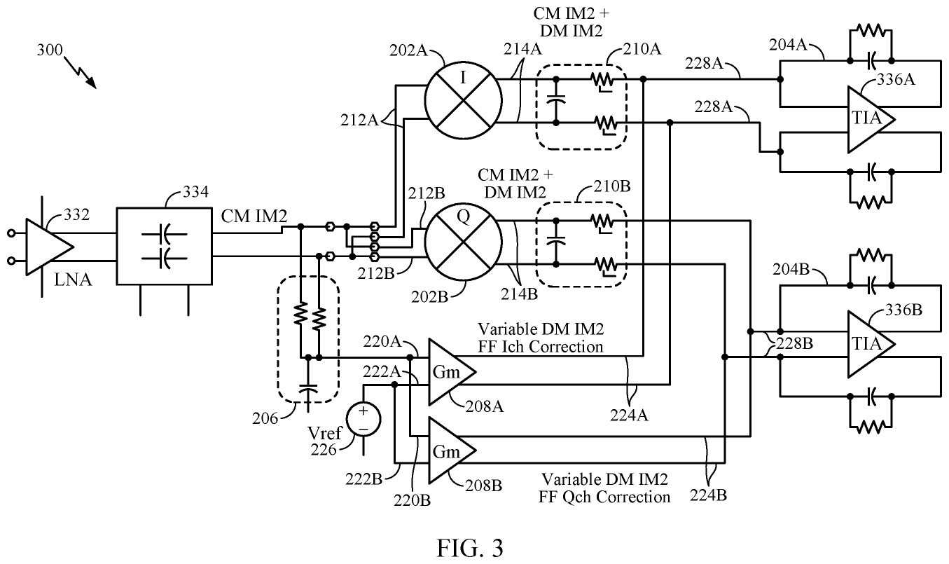

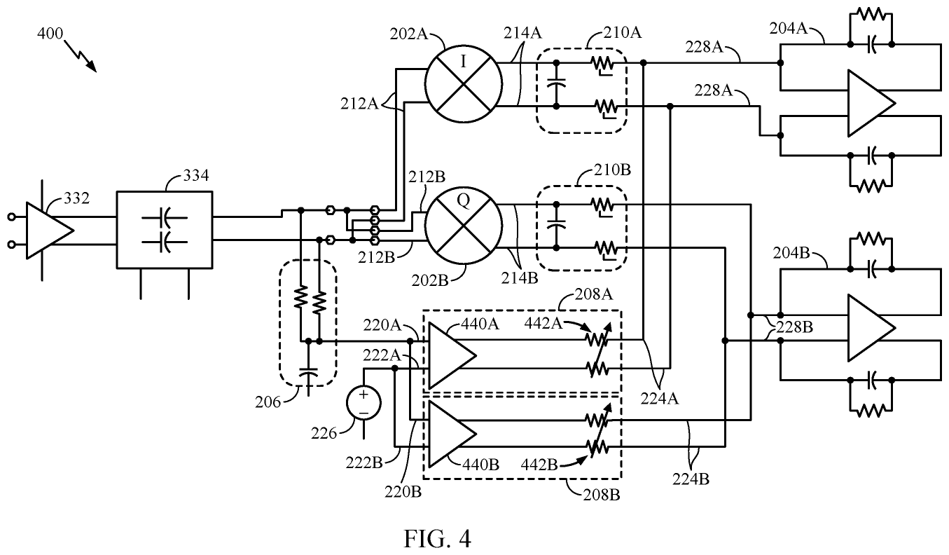

Certain aspects of the present disclosure generally relate to an example receiver with a mixer and a feed-forward path to cancel the IM2 distortion and improve the IM2 calibration of the receiver (e.g., allowing for online IM2 calibration outside of the manufacturing facility). For instance, the receive chain may include a conversion circuit that compares a common-mode IM2 signal at the input of the mixer to a baseband reference signal, and feeds forward on the output of the mixer a differential current that is designed to cancel the differential-mode IM2 signal output by the mixer, as further described herein with respect to FIG. 2. In certain aspects, the conversion circuit may convert a sensed voltage at the input to a cancellation current applied to the output of the mixer. The conversion circuit may be implemented by a transconductor, which may include a transconductance amplifier (as described herein with respect to FIG. 3) or a voltage amplifier having an output coupled to a variable impedance circuit (as described herein with respect to FIG. 4).

Cancelling the differential-mode IM2 output by the mixer may eliminate or reduce the interdependence between the in-phase and quadrature channels of the mixer. As a result, the differential-mode IM2 cancellation may simplify the calibration process of the receiver by enabling independent calibrations for the in-phase and quadrature channels. Further, such a simplified calibration process may also enable online calibration (e.g., when the RFIC is deployed and operating in the market), which in turn may provide a more robust receiver that is capable of adjusting to various operating conditions (e.g., variances in temperature, mismatches in the mixers (e.g., resistance, capacitance, gate voltages, etc.), impedance of the local oscillators, and impedance mismatches) that left uncalibrated may degrade the performance of the receiver. For instance, the mismatches between the in-phase and quadrature channels of the mixer may be temperature dependent. Instead of testing the receiver at various temperatures in a manufacturing facility, the temperature variances may be calibrated using the feed-forward path described herein while the receiver is deployed to the end-user, for example, when a mobile phone is online in the market.

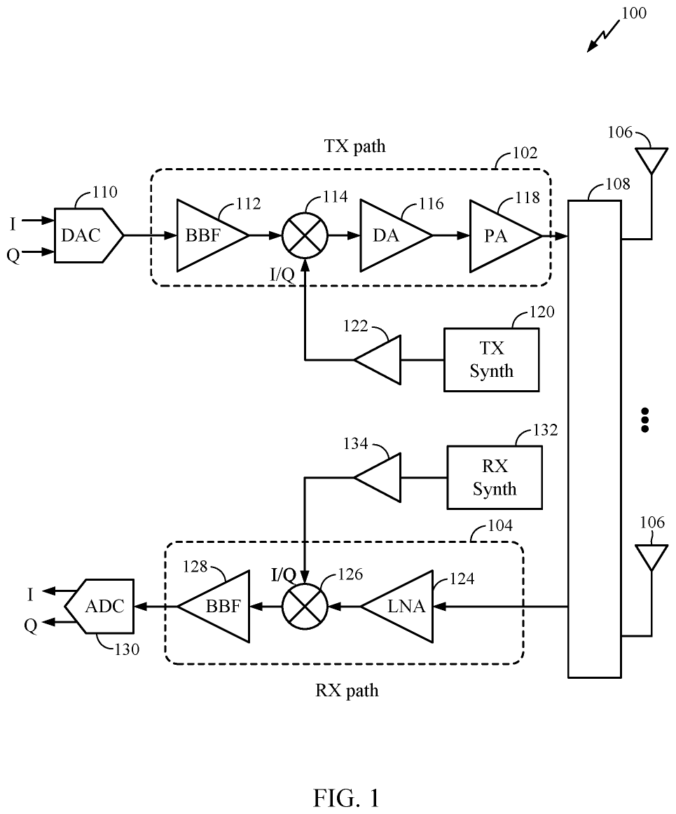

FIG. 1 is a block diagram of an example RF front-end 100, in accordance with certain aspects of the present disclosure. The RF front-end 100 may include a receiver with a mixer and a feed-forward path connected in parallel with the mixer, as further described herein with respect to FIGS. 2-4.

The RF front-end 100 includes at least one transmit (TX) path 102 (also known as a transmit chain) for transmitting signals via one or more antennas 106 and at least one receive (RX) path 104 (also known as a receive chain) for receiving signals via the antennas 106. When the TX path 102 and the RX path 104 share an antenna 106, the paths may be connected with the antenna via an interface 108, which may include any of various suitable RF devices, such as a switch 140, a duplexer, a diplexer, a multiplexer, and the like.

Receiving in-phase (I) or quadrature (Q) baseband analog signals from a digital-to-analog converter (DAC) 110, the TX path 102 may include a baseband filter (BBF) 112, a mixer 114, a driver amplifier (DA) 116, and a power amplifier (PA) 118. The BBF 112, the mixer 114, the DA 116, and the PA 118 may be included in a semiconductor device such as a radio frequency integrated circuit (RFIC).

The BBF 112 filters the baseband signals received from the DAC 110, and the mixer 114 mixes the filtered baseband signals with a transmit local oscillator (LO) signal to convert the baseband signal of interest to a different frequency (e.g., upconvert from baseband to a radio frequency). This frequency conversion process produces the sum and difference frequencies between the LO frequency and the frequencies of the baseband signal of interest. The sum and difference frequencies are referred to as the beat frequencies. The beat frequencies are typically in the RF range, such that the signals output by the mixer 114 are typically RF signals, which may be amplified by the DA 116 and/or by the PA 118 before transmission by the antenna 106.

The RX path 104 may include a low noise amplifier (LNA) 124, a mixer 126, and a baseband filter (BBF) 128. The LNA 124, the mixer 126, and the BBF 128 may be included in a RFIC, which may or may not be the same RFIC that includes the TX path components. RF signals received via the antenna 106 may be amplified by the LNA 124, and the mixer 126 mixes the amplified RF signals with a receive local oscillator (LO) signal to convert the RF signal of interest to a different baseband frequency (e.g., downconvert). The baseband signals output by the mixer 126 may be filtered by the BBF 128 before being converted by an analog-to-digital converter (ADC) 130 to digital I or Q signals for digital signal processing. In certain aspects, the mixer 126 may have a feed-forward path connected in parallel thereto, which reduces intermodulation distortions, as further described herein with respect to FIGS. 2-4.

While it is desirable for the output of an LO to remain stable in frequency, tuning to different frequencies indicates using a variable-frequency oscillator, which may involve compromises between stability and tunability. Contemporary systems may employ frequency synthesizers with a voltage-controlled oscillator (VCO) to generate a stable, tunable LO with a particular tuning range. Thus, the transmit LO may be produced by a TX frequency synthesizer 120, which may be buffered or amplified by amplifier 122 before being mixed with the baseband signals in the mixer 114. Similarly, the receive LO may be produced by an RX frequency synthesizer 132, which may be buffered or amplified by amplifier 134 before being mixed with the RF signals in the mixer 126.

While FIG. 1 provides an RF front-end as an example application in which certain aspects of the present disclosure may be implemented to facilitate understanding, certain aspects described herein related to a mixer with an associated feed-forward path may be utilized in various other suitable electronic systems. Therefore, the present disclosure is not limited to a receiver architecture, but may generally be applied to any downconverted signal having a second-order nonlinear distortion.

### Example Receiver

FIG. 2 is a schematic view of an example receiver 200, in accordance with certain aspects of the present disclosure. The receiver 200 may include all or some of the components in the receive path of an RF front-end, for example. The receiver 200 may be a direct conversion receiver. As shown, the receiver 200 may include a mixer 202, a baseband filter 204, common-mode sensing circuitry 206, and a conversion circuit 208. In aspects, the receiver 200 may also include a transmit filter 210.

The mixer 202 may be a direct downconversion passive mixer using no intermediate frequency for the downconversion. The passive mixer 202 has differential input terminals 212 and differential output terminals 214. The differential input terminals 212 may be electrically coupled to differential components of the received signal on the receiver 200 (e.g., from the antenna in an RF front-end). For example, the received signal may be received by an antenna and converted by a low-noise amplifier (such as the LNA 124) to differential signals, such as differential in-phase (I) and quadrature (Q) signals. The differential input terminals 212 may be electrically coupled to the output of the LNA, as further described herein with respect to FIGS. 3 and 4. The differential output terminals 214 may be electrically coupled to the differential inputs of the transmit filter 210.

The common-mode sensing circuitry 206 may be a variable impedance circuit and/or a phase shift circuit that provides a phase delay to a differential signal present at the differential input terminals 212 of the mixer 202. The common-mode sensing circuitry 206 is coupled to the differential input terminals of the mixer 202 and configured to sense a common-mode signal component (e.g., a common-mode voltage signal) of a signal present at the differential input terminals 212. The common-mode sensing circuitry 206 may include at least one capacitive element 216 and at least one resistive element 218. The capacitive element(s) 216 and resistive element(s) 218 may have values to provide a phase delay that matches the phase delay encountered at the differential output terminals 214 of the mixer 202. The phase delay at the output of the mixer may be caused by a capacitance and a resistance between the differential output terminals 214 and inputs 228 of the baseband filter 204. In certain aspects, the capacitive element(s) 216 and/or resistive element(s) 218 may be adjustable to reproduce the phase delay encountered at the differential output terminals of the mixer. For instance, the capacitive element(s) 216 may include a tunable capacitor, such as a switched-capacitor array or a digitally tunable capacitor, and the resistive element(s) 218 may include a tunable resistor, such as a potentiometer.

The conversion circuit 208 is coupled to the common-mode sensing circuitry 206. The conversion circuit 208 may convert the common-mode signal to a second differential signal (e.g., a differential current signal) presented to the differential output terminals 214 of the mixer 202 and the inputs 228 of the baseband filter 204. The conversion circuit 208 may be implemented with a programmable amplifier (e.g., a variable transconductance amplifier or a voltage amplifier with a variable resistive element coupled to an output of the voltage amplifier) that detects a first type of intermodulation distortion (e.g., a low-frequency common-mode IM2) generated by the passive mixer 202 and outputs an electric current designed to eliminate or reduce a second type of intermodulation distortion (e.g., a differential-mode IM2) output by the passive mixer 202. In some cases, the two types of IM2 distortion (e.g., common-mode IM2 at the mixer input and differential-mode IM2 at the mixer output) may occur at the same frequency or proximal frequencies, which provides for eliminating, or at least reducing, the second type of intermodulation distortion. For instance, the conversion circuit 208 may convert a common-mode intermodulation distortion (e.g., IM2) signal to a differential signal that reduces a differential intermodulation distortion (e.g., IM2) output by the passive mixer 202. In aspects, the conversion circuit 208 may include a transconductor configured to output the differential current based on a difference between a reference voltage and the common-mode signal. A gain of the transconductor may be adjustable and set as a result of a calibration operation.

The conversion circuit 208 includes a first input terminal 220, a second input terminal 222, and output terminals 224. The first input terminal 220 is electrically coupled to the common-mode sensing circuitry 206. The second input terminal 222 is electrically coupled to a reference voltage source 226, which provides a baseband reference signal. The output terminals 224 of the conversion circuit 208 are electrically coupled to the differential output terminals 214 of the passive mixer 202 and/or to the inputs 228 of the baseband filter 204.

The conversion circuit 208 may compare the phase-shifted signals (e.g., a common-mode intermodulation distortion signal) to the baseband reference signal and detect the intermodulation distortion generated by the passive mixer 202 based on such a comparison. For instance, the conversion circuit 208 may convert the common-mode intermodulation distortion signal to a differential signal based on a difference between the baseband reference signal and the common-mode intermodulation distortion signal. The conversion circuit 208 may adjust an amplitude of the sensed common-mode signal to a value that offsets the amplitude of the differential intermodulation distortion output by the passive mixer, resulting in a cancellation of the differential intermodulation distortion. The differential signal output by the conversion circuit 208 may be a differential output current.

The transmit filter 210 may be electrically coupled between the mixer 202 and the baseband filter 204, where the inputs of the transmit filter 210 may be electrically coupled to the output terminals 214 of the mixer 202 and the outputs of the transmit filter 210 may be electrically coupled to the output terminals 224 of the conversion circuit 208 and the inputs 228 of the baseband filter. The output terminals 224 of the conversion circuit 208 may apply the differential signal that reduces the differential intermodulation distortion (e.g., IM2) output by the passive mixer 202. The transmit filter 210 may be a low-pass or high-pass filter that filters interference generated from the transmit path on the RF front-end. For instance, signals generated from the transmit path on the RF front-end may leak into the receive path and interfere with the receive-path signals, and the transmit filter 210 may be configured to reduce such interference.

The baseband filter 204 includes inputs 228 coupled to the differential output terminals 214 of the mixer 202. The baseband filter 204 may be a bandpass filter that filters the baseband signal from the downconverted signal. The baseband filter 204 may output the filtered downconverted signal to an ADC (e.g., the ADC 130) on the receive path of an RF front-end (e.g., RX path 104 of the RF front-end 100). For example, the baseband filter 204 may include outputs 230 coupled to the ADC (not shown) of the RF front-end.

In certain aspects, the receiver may have a multi-core mixer circuit with in-phase and quadrature channels. FIG. 3 is a schematic view of an example receiver 300 having in-phase and quadrature channels, in accordance with certain aspects of the present disclosure. As shown, the receiver 300 may have in-phase channel circuitry and quadrature channel circuitry, each having separate feed-forward intermodulation distortion cancellation paths.

The in-phase channel circuitry may include a mixer 202A, a baseband filter 204A, and a conversion circuit 208A. The quadrature channel circuitry may have complementary components including a mixer 202B, a baseband filter 204B, and a conversion circuit 208B. As such, the in-phase channel circuitry may be separately calibrated or adjusted to cancel the distortion of the in-phase passive mixer 202A, and the quadrature channel circuitry may also have a separate calibration and adjustment to cancel the distortion of the quadrature passive mixer 202B. For example, due to different non-linear characteristics exhibited in the in-phase passive mixer 202A and the quadrature passive mixer 202B, the in-phase conversion circuit 208A may apply a different gain to the differential output signal relative to the gain of the quadrature conversion circuit 208B. In certain aspects as illustrated in FIG. 3, each of the conversion circuits 208A, 208B may be implemented with a transconductor (e.g., a transconductance amplifier converting input voltage to output current). In certain aspects, the gains of the conversion circuits 208A, 208B may be configured to be set independent of one another. For example, the gain of the Q-channel conversion circuit 208B may be different from the gain of the I-channel conversion circuit 208A.

In certain aspects, a differential low-noise amplifier (LNA) 332 (similar to LNA 124) may be electrically coupled to the differential input terminals 212A, 212B of the mixers 202A, 202B. In some cases, AC coupling capacitors 334 may be electrically coupled between outputs of the LNA 332 and the inputs of the passive mixers 202A, 202B. The coupling capacitors 334 may block an intermodulation distortion component generated in the LNA 332.

The baseband filters 204A, 204B may each include a transimpedance amplifier (TIA) 336A, 336B that converts the current output by the passive mixer 202 to an output voltage (e.g., Vout). The low impedance of the transimpedance amplifier 336A, 336B and impedance of the transmit filter 210A, 210B may provide isolation for the feed-forward path of the respective conversion circuit 208A, 208B.

In certain aspects, each of the conversion circuits 208A, 208B may be implemented by a different type of transconductor, such as by a voltage amplifier having an output coupled to a variable impedance circuit. FIG. 4 is a schematic view of an example receiver 400 having conversion circuits implemented as an operational amplifier with an output coupled to a variable impedance circuit, in accordance with certain aspects of the present disclosure. As shown, each of the conversion circuits 208A, 208B includes an amplifier 440A, 440B (e.g., a voltage amplifier) and a variable impedance circuit 442A, 442B (e.g., a variable resistive element or array). The amplifier 440A, 440B may generate a differential voltage based on the common-mode intermodulation distortion detected on the input side of the passive mixer 202A, 202B, as described herein with respect to FIG. 2. The variable impedance circuit 442A, 442B may be adjusted to output a differential current at a particular amplitude that cancels the differential-mode intermodulation distortion output by the passive mixer 202A, 202B. The variable impedance circuit 442A, 442B may be implemented as a variable resistor or as a switched array of resistors, for example. With this type of transconductor, the gain of the amplifier 440A, 440B may be fixed, and a resistance of the variable impedance circuit 442A, 442B may be adjusted to output the differential current at a particular amplitude that cancels the differential-mode intermodulation distortion output by the passive mixer 202A, 202B.

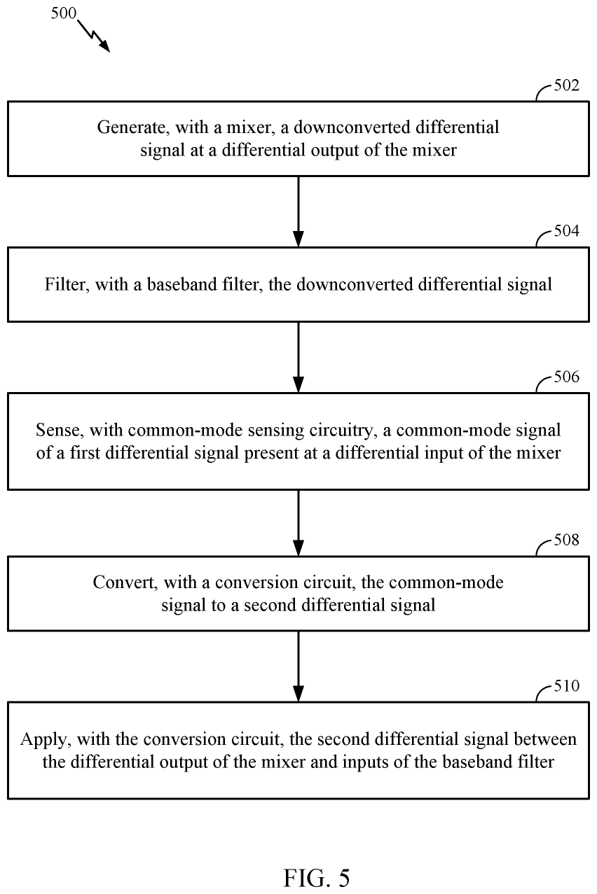

FIG. 5 is a flow diagram of example operations 500 for downconversion with a receiver, in accordance with certain aspects of the present disclosure. The operations 500 may be performed by a receiver (e.g., the receiver 200, 300, or 400) as described herein with respect to FIGS. 2-4. In aspects, the receiver may be a direct conversion receiver.

The operations 500 begin, at block 502, where the receiver generates, with a mixer (e.g., one of the mixers 202, which may be a passive mixer), a downconverted differential signal at a differential output of the mixer. At block 504, the receiver may filter, with a baseband filter (e.g., the baseband filter 204), the downconverted differential signal. At block 506, the receiver may sense, with common-mode sensing circuitry (e.g., the common-mode sensing circuitry 206), a common-mode signal (e.g., a common-mode voltage signal) of a first differential signal present at a differential input of the mixer. At block 508, the receiver may convert, with a conversion circuit (e.g., the conversion circuitry 208), the common-mode signal to a second differential signal (e.g., a differential current signal). At block 510, the receiver may apply, with the conversion circuit, the second differential signal between the differential output of the mixer and inputs of the baseband filter.

The common-mode sensing circuitry of operations 500 may include at least one capacitive element (e.g., the capacitive element 216) and at least one resistive element (e.g., the resistive elements 218). The at least one capacitive element and the at least one resistive element may have values to provide a first amount of phase delay that matches a second amount of phase delay at the differential output terminals of the mixer caused by a capacitance and a resistance between the differential output terminals of the mixer and the inputs of the baseband filter. In other words, the receiver may apply, with common-mode sensing circuitry, a first amount of phase delay to the first differential signal present at the differential input of the mixer. In certain aspects, the first amount of phase delay may match a second amount of phase delay at the differential output of the mixer caused by a capacitance and a resistance between the differential output of the mixer and the inputs of the baseband filter. The receiver may convert the common-mode signal to the second differential signal based on a difference between a baseband reference signal and the common-mode signal. The receiver may apply the second differential signal by at least in part adjusting a gain of the conversion circuit.

The operations 500 may further include performing the downconversion on a plurality of channels with a plurality of mixers and conversion circuits as described herein with respect to FIGS. 3 and 4. For example, the receiver may include an additional mixer (e.g., the mixer 202B of FIGS. 3 and 4) having differential input terminals and differential output terminals. In aspects, the mixer is an in-phase channel mixer, and the additional mixer is a quadrature channel mixer. The differential input terminals of the additional mixer are coupled to the differential input terminals of the mixer. The receiver may also include an additional baseband filter (e.g., the baseband filter 204B of FIGS. 3 and 4) having inputs coupled to the differential output terminals of the additional mixer. The receiver may further include an additional conversion circuit (e.g., the conversion circuit 208B of FIGS. 3 and 4) coupled to the common-mode sensing circuitry and configured to convert the common-mode signal to a third differential signal presented to the differential output terminals of the additional mixer and the inputs of the additional baseband filter. In certain aspects, a gain of the additional conversion circuit is different from a gain of the conversion circuit. In aspects, the receiver may adjust the gains of the conversion circuits independent of one another.

In aspects, the operations 500 may further include performing online calibration of the receiver while applying the second differential signal. For example, the receiver may be implemented in a wireless communication device (e.g., a mobile phone, smart phone, tablet, or laptop), and the gain of the conversion circuit may be calibrated in online operation to the end user.

According to certain aspects, the conversion circuit of operations 500 may include a transconductor configured to output a differential current based on a difference between a reference voltage and the common-mode signal. In aspects, the conversion circuit may include a voltage amplifier and a variable resistive element coupled to an output of the voltage amplifier. In such cases, a gain of the voltage amplifier may be fixed. In aspects, the reference voltage is a baseband reference voltage. A gain of the transconductor may be adjustable and set as a result of a calibration operation.

### CONCLUSION

Certain aspects of the present disclosure provide a receiver comprising a mixer having a differential input and a differential output. The receiver also includes common-mode sensing circuitry for sensing a common-mode voltage of a differential input signal present at the differential input of the passive mixer. The common-mode sensing circuitry provides a signal to conversion circuitry that converts the common-mode signal to a differential signal coupled to the differential output of the mixer and to an input of a baseband filter.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation and details of the methods and apparatus described above without departing from the scope of the claims.

1. A receiver, comprising:
a mixer having differential input terminals and differential output terminals;
a baseband filter having inputs coupled to the differential output terminals of the mixer;
common-mode sensing circuitry coupled to the differential input terminals of the mixer and configured to sense a common-mode signal of a first differential signal present at the differential input terminals of the mixer; and
a conversion circuit coupled to the common-mode sensing circuitry and configured to convert the common-mode signal to a second differential signal presented to the differential output terminals of the mixer and the inputs of the baseband filter.

2. The receiver of claim 1, wherein the common-mode sensing circuitry includes at least one capacitive element and at least one resistive element.

3. The receiver of claim 2, wherein the at least one capacitive element and the at least one resistive element have values to provide a first amount of phase delay that matches a second amount of phase delay at the differential output terminals of the mixer caused by a capacitance and a resistance between the differential output terminals of the mixer and the inputs of the baseband filter.

4. The receiver of claim 1, wherein the mixer is a passive mixer.

5. The receiver of claim 1, wherein the common-mode signal is a common-mode voltage signal.

6. The receiver of claim 1, wherein the second differential signal is a differential current signal.

7. The receiver of claim 1, wherein the conversion circuit comprises a transconductor configured to output a differential current based on a difference between a reference voltage and the common-mode signal.

8. The receiver of claim 7, wherein the reference voltage is a baseband reference voltage.

9. The receiver of claim 7, wherein a gain of the transconductor is adjustable and set as a result of a calibration operation.

10. The receiver of claim 7, wherein the transconductor comprises a voltage amplifier and a variable resistive element coupled to an output of the voltage amplifier and wherein a gain of the voltage amplifier is fixed.

11. The receiver of claim 1, wherein the receiver is a direct conversion receiver.

12. The receiver of claim 1, further comprising:
an additional mixer having differential input terminals and differential output terminals, wherein the mixer is an in-phase channel mixer, wherein the additional mixer is a quadrature channel mixer, and wherein the differential input terminals of the additional mixer are coupled to the differential input terminals of the mixer;
an additional baseband filter having inputs coupled to the differential output terminals of the additional mixer; and
an additional conversion circuit coupled to the common-mode sensing circuitry and configured to convert the common-mode signal to a third differential signal presented to the differential output terminals of the additional mixer and the inputs of the additional baseband filter.

13. The receiver of claim 12, wherein a gain of the additional conversion circuit is different from a gain of the conversion circuit.

14. The receiver of claim 13, wherein the gains of the conversion circuits are configured to be set independent of one another.

15. A method of downconversion with a receiver, comprising:
generating, with a mixer, a downconverted differential signal at a differential output of the mixer;
filtering, with a baseband filter, the downconverted differential signal;
sensing, with common-mode sensing circuitry, a common-mode signal of a first differential signal present at a differential input of the mixer;
converting, with a conversion circuit, the common-mode signal to a second differential signal; and
applying, with the conversion circuit, the second differential signal between the differential output of the mixer and inputs of the baseband filter.

16. The method of claim 15, wherein sensing the common-mode signal comprises applying a first amount of phase delay to the first differential signal present at the differential input of the mixer, wherein the first amount of phase delay matches a second amount of phase delay at the differential output of the mixer caused by a capacitance and a resistance between the differential output of the mixer and the inputs of the baseband filter.

17. The method of claim 15, wherein converting the common-mode signal comprises converting the common-mode signal to the second differential signal based on a difference between a baseband reference signal and the common-mode signal.

18. The method of claim 15, wherein converting the common-mode signal comprises adjusting a gain of the conversion circuit.

19. The method of claim 15, further comprising:
performing the downconversion on a plurality of channels with a plurality of mixers and a plurality of conversion circuits; and
adjusting gains of the conversion circuits independent of one another.

20. The method of claim 15, further comprising performing online calibration of the receiver while applying the second differential signal.
